(19) United States
(12) Patent Application Publication
(10) Pub. No.: US 2026/0223718 A1
(43) Pub. Date: Jul. 30, 2026

(54) SEMICONDUCTOR DEVICE

(71) Applicant: ROHM CO., LTD., Kyoto-shi (JP)

(72) Inventor: Tsunehisa ONO, Kyoto-shi (JP)

(21) Appl. No.: 19/630,846

(22) Filed: Mar. 27, 2026

Related U.S. Application Data
(63) Continuation of application No. PCT/JP2024/034602, filed on Sep. 27, 2024.

(30) Foreign Application Priority Data
Oct. 4, 2023 (JP) 2023-172652

(51) Int. Cl. H10W 72/50; H10D 80/20; H10W 70/40; H10W 74/10; H10W 90/00; H10W 90/10

(52) U.S. Cl. CPC H10W 72/528; H10D 80/251; H10W 70/481; H10W 72/527; H10W 74/111; H10W 90/10; H10W 90/736; H10W 90/753; H10W 90/756; H10W 90/811

(57) ABSTRACT

A semiconductor device includes: one or more leads; one or more semiconductor elements disposed on a first side in a thickness direction with respect to the one or more leads; a plurality of wires each of which is electrically connected to at least one of the one or more leads and the one or more semiconductor elements; and a sealing resin that covers the one or more semiconductor elements, the plurality of wires, and at least a portion of the one or more leads. The plurality of wires include a first wire and a second wire. The second wire is curved in a convex shape toward the first wire as viewed in the thickness direction. The second wire extends across the first wire as viewed in the thickness direction and is spaced apart from the first wire in the thickness direction.

### TECHNICAL FIELD

### The present disclosure relates to semiconductor devices

### BACKGROUND ART

Various configurations of semiconductor devices incorporating semiconductor elements have been proposed. WO 2019/203139 discloses an example of a conventional semiconductor device. The semiconductor device disclosed in the document includes a lead, a semiconductor element, a plurality of wires, and a sealing resin. Some of the wires are electrically connected to the semiconductor element. The sealing resin covers the semiconductor element, the wires, and a portion of the lead. The sealing resin is formed by injecting molten resin into a mold cavity and then solidifying the resin. During injection, the flow of resin may deform the wire loops, resulting in wire sweep. Such wire sweep may cause adjacent wires to come into contact, which may adversely affect the electrical performance of the semiconductor device.

### BRIEF DESCRIPTION OF THE DRAWINGS

FIG. 1 is a perspective view of a semiconductor device according to a first embodiment of the present disclosure.

FIG. 2 is a plan view of the semiconductor device according to the first embodiment of the present disclosure.

FIG. 3 is a plan view of the semiconductor device according to the first embodiment of the present disclosure.

FIG. 4 is a front view of the semiconductor device according to the first embodiment of the present disclosure.

FIG. 5 is a rear view of the semiconductor device according to the first embodiment of the present disclosure.

FIG. 6 is a right-side view of the semiconductor device according to the first embodiment of the present disclosure.

FIG. 7 is a left-side view of the semiconductor device according to the first embodiment of the present disclosure.

FIG. 8 is a sectional view taken along line VIII-VIII in FIG. 3.

FIG. 9 is a sectional view taken along line IX-IX in FIG. 3.

FIG. 10 is a sectional view taken along line X-X in FIG. 3.

FIG. 11 is a sectional view taken along line XI-XI in FIG. 3.

FIG. 12 is a sectional view taken along line XII-XII in FIG. 3.

FIG. 13 is an enlarged partial sectional view taken along line XIII-XIII in FIG. 3.

FIG. 14 is an enlarged partial sectional view taken along line XIV-XIV in FIG. 3.

FIG. 15 is an enlarged partial view of FIG. 3.

FIG. 16 is a lateral view schematically showing the arrangement of a first wire and a second wire.

FIG. 17 is a lateral view schematically showing the arrangement of a first wire and a second wire, according to a variation of the first embodiment.

FIG. 18 is a plan view schematically showing the arrangement of a first wire and a second wire, according to another variation.

FIG. 19 is a lateral view schematically showing the arrangement of the first wire and the second wire shown in FIG. 18.

FIG. 20 is a plan view schematically showing the arrangement of a first wire and a second wire, according to a yet another variation.

FIG. 21 is a lateral view schematically showing the arrangement of the first wire and the second wire shown in FIG. 20.

### DETAILED DESCRIPTION OF EMBODIMENTS

The following specifically describes preferred embodiments of the present disclosure with reference to the drawings.

In the present disclosure, terms such as “first”, “second”, “third”, and so on are used only as labels and are not necessarily intended to imply any order of the items to which they refer.

In the present disclosure, the expressions “An object A is formed in an object B”, and “An object A is formed on an object B” imply cases where, unless otherwise specifically noted, “the object A is formed directly in or on the object B”, and “the object A is formed in or on the object B, with something else interposed between the object A and the object B.” Likewise, the expressions “An object A is arranged in an object B”, and “An object A is arranged on an object B” imply cases where, unless otherwise specifically noted, “the object A is arranged directly in or on the object B”, and “the object A is arranged in or on the object B, with something else interposed between the object A and the object B”. Further, the expression “An object A is positioned on an object B” implies cases where, unless otherwise specifically noted, “the object A is positioned on the object B, in contact with the object B”, and “the object A is positioned on the object B, with something else interposed between the object A and the object B”. Still further, the expression “An object A overlaps with an object B as viewed in a certain direction” implies cases where, unless otherwise specifically noted, “the object A overlaps with the entirety of the object B”, and “the object A overlaps with a portion of the object B”. Still further, in the present disclosure, the expression “A surface A faces a direction B (one side or the other side in that direction) is not limited to a case where the surface A forms an angle of 90° with the direction B, but includes a case where the surface A is inclined with respect to the direction B.

### FIRST EMBODIMENT:

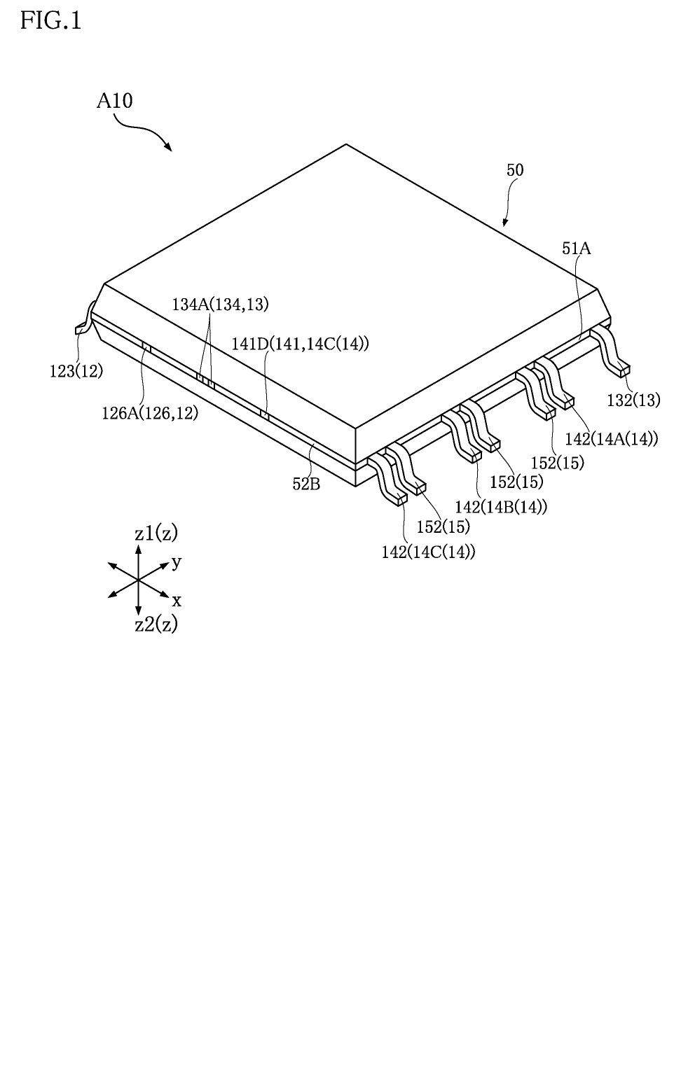

FIGS. 1 to 16 show a semiconductor device according to a first embodiment of the present disclosure. The semiconductor device A10 of the present embodiment includes a first lead 11, a second lead 12, a third lead 13, a plurality of fourth leads 14, a plurality of fifth leads 15, a plurality of sixth leads 16, a drive element 21, a control element 22, a plurality of first switching elements 31, a plurality of second switching elements 32, and a sealing resin 50. The semiconductor device A10 additionally includes a plurality of wires 41, a plurality of wires 42, a plurality of wires 431, a plurality of wires 432, a plurality of wires 441, a wire 442, a plurality of wires 45, a plurality of wires 46, and a plurality of wires 47.

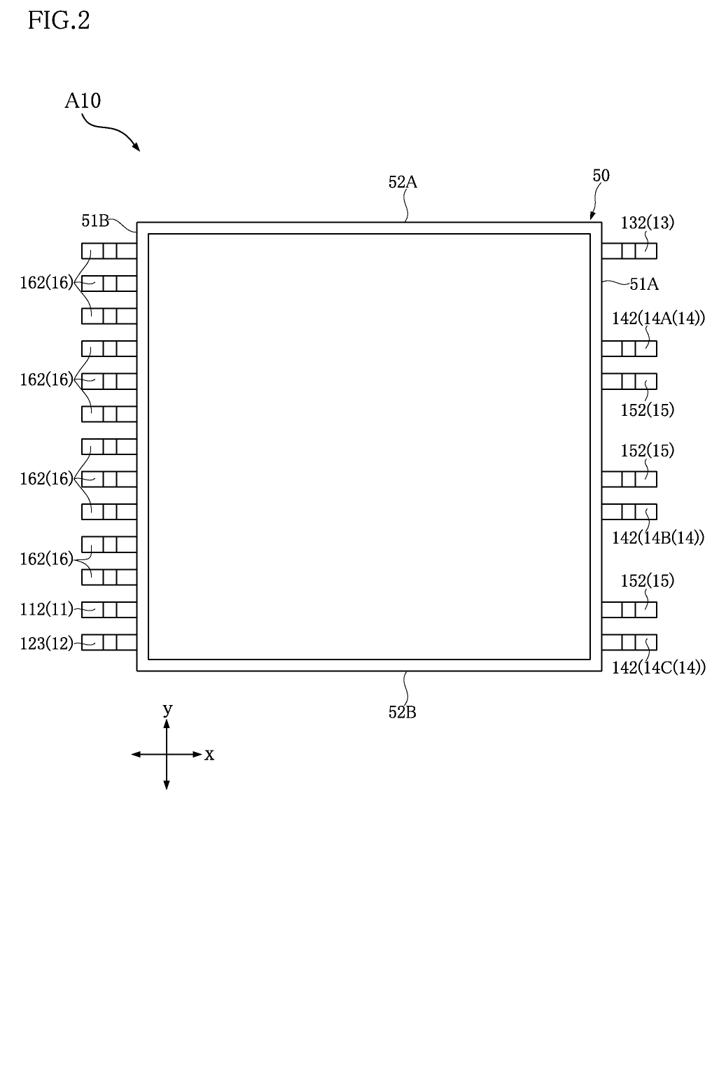

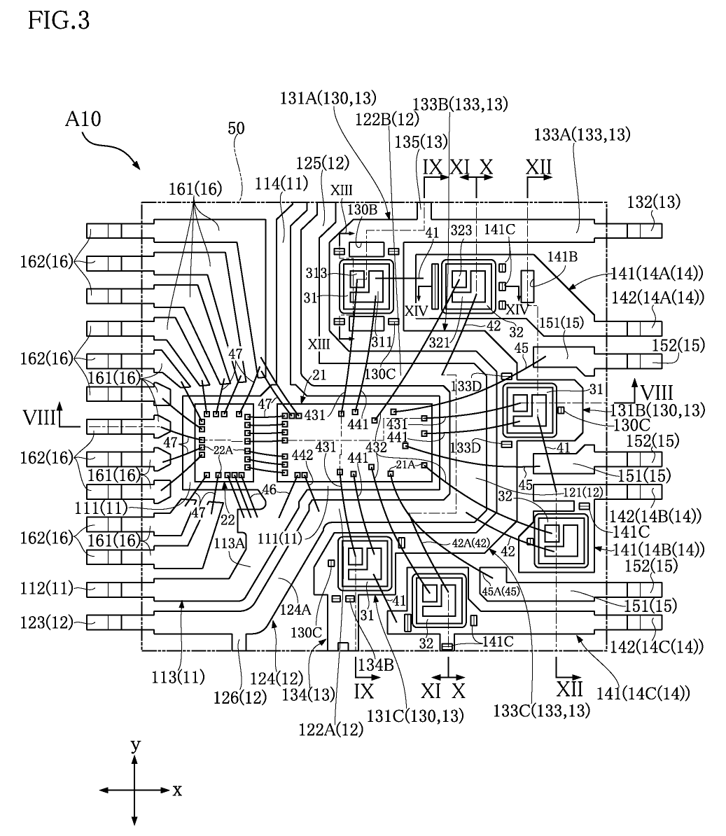

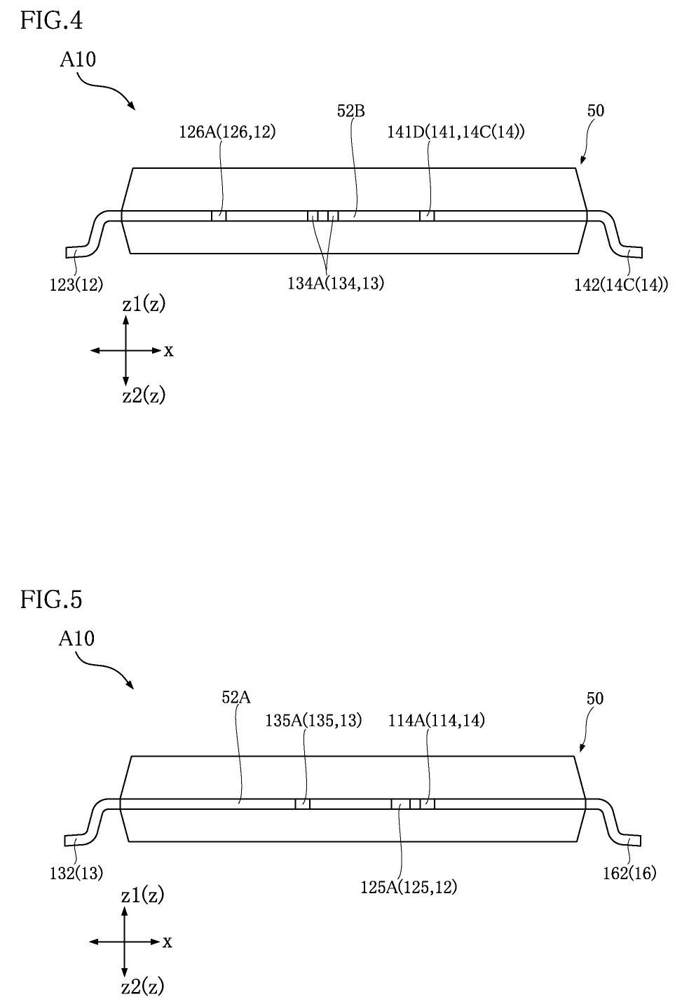

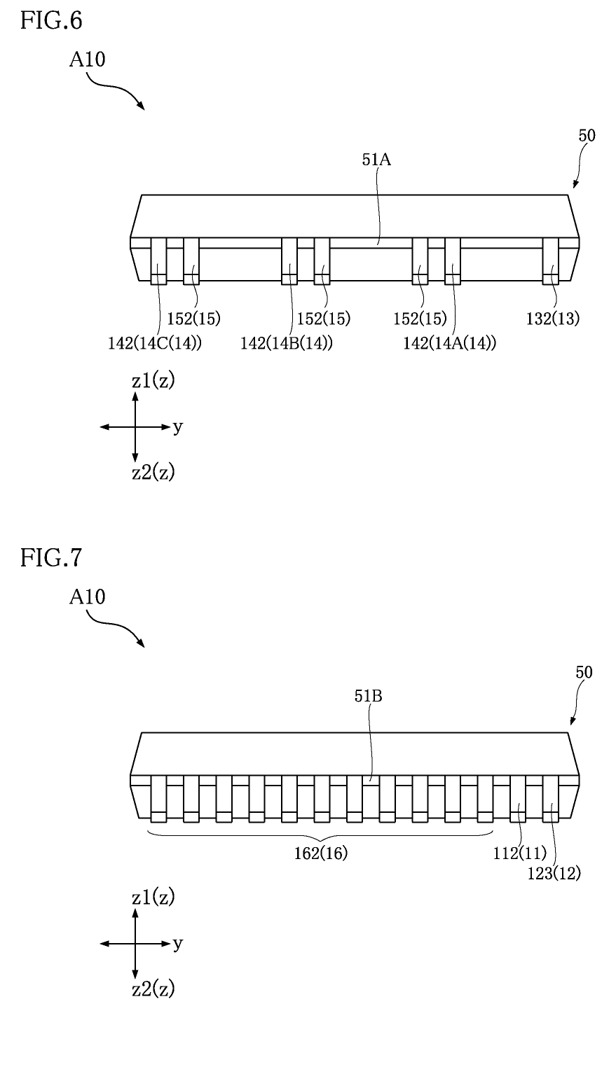

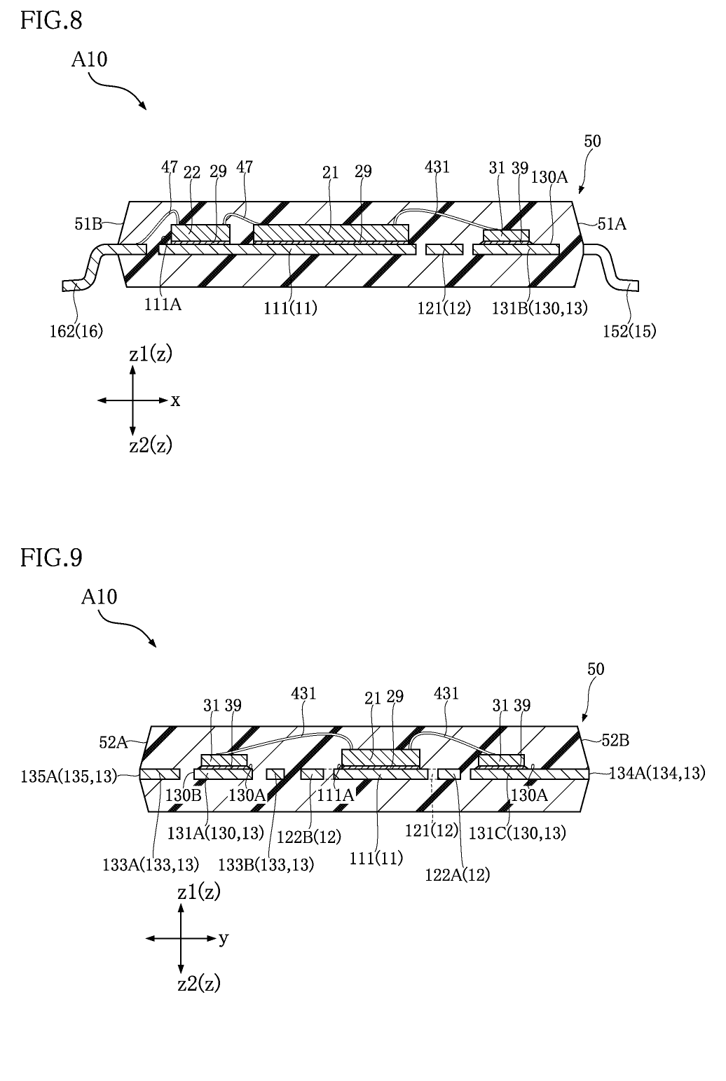

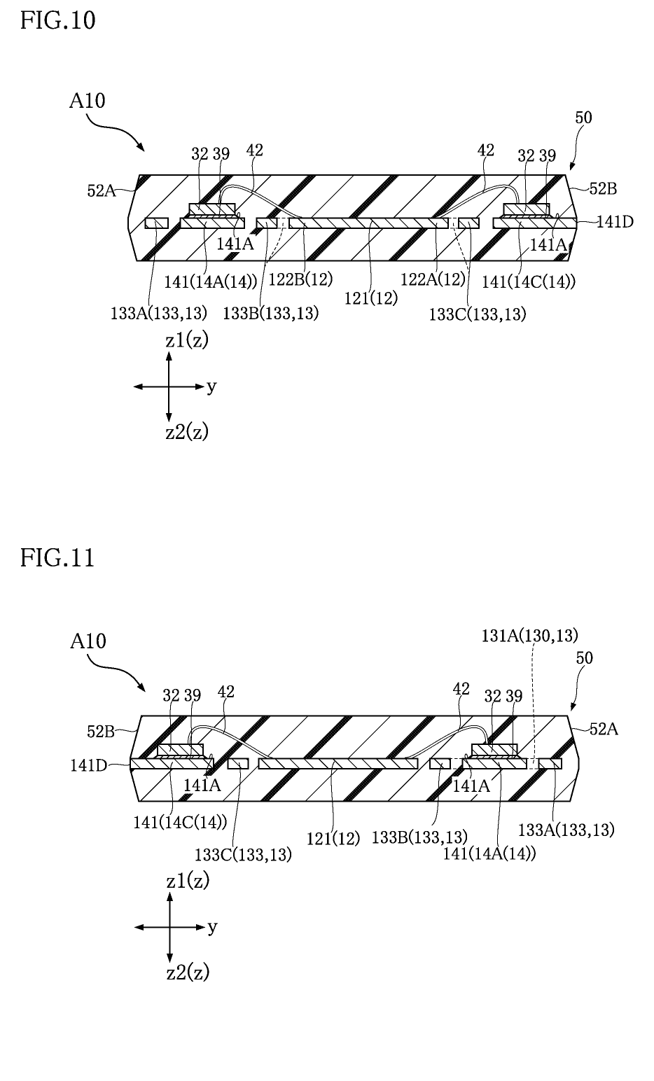

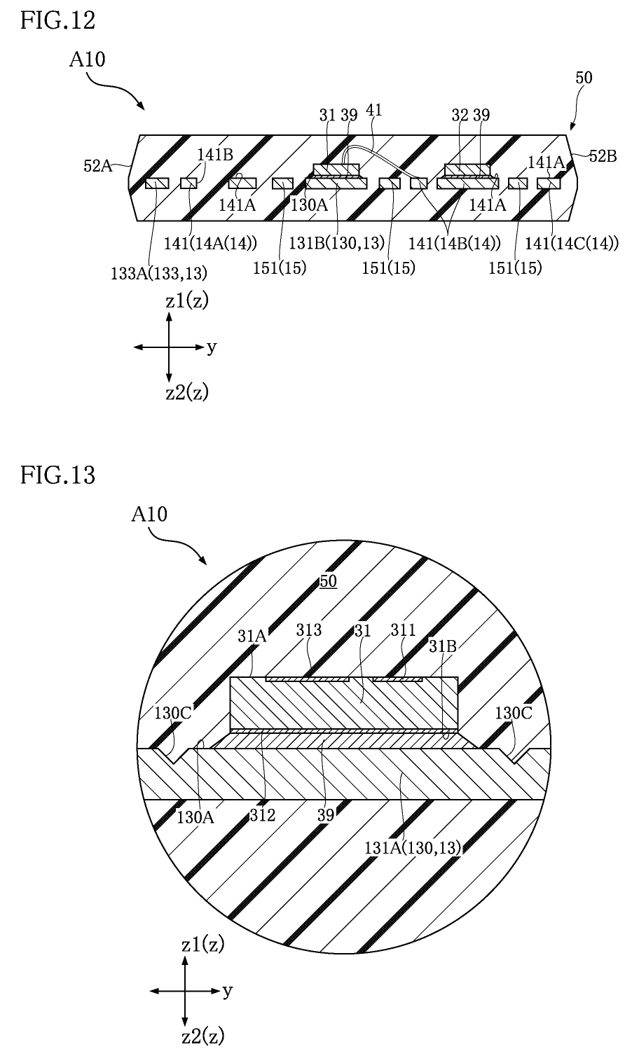

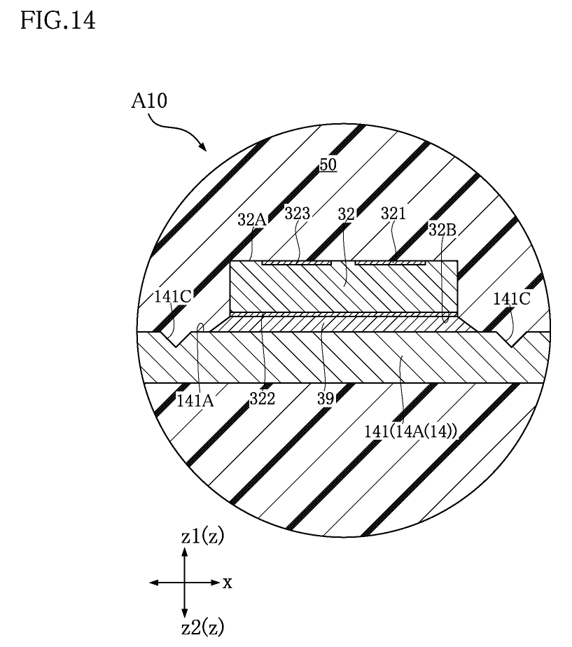

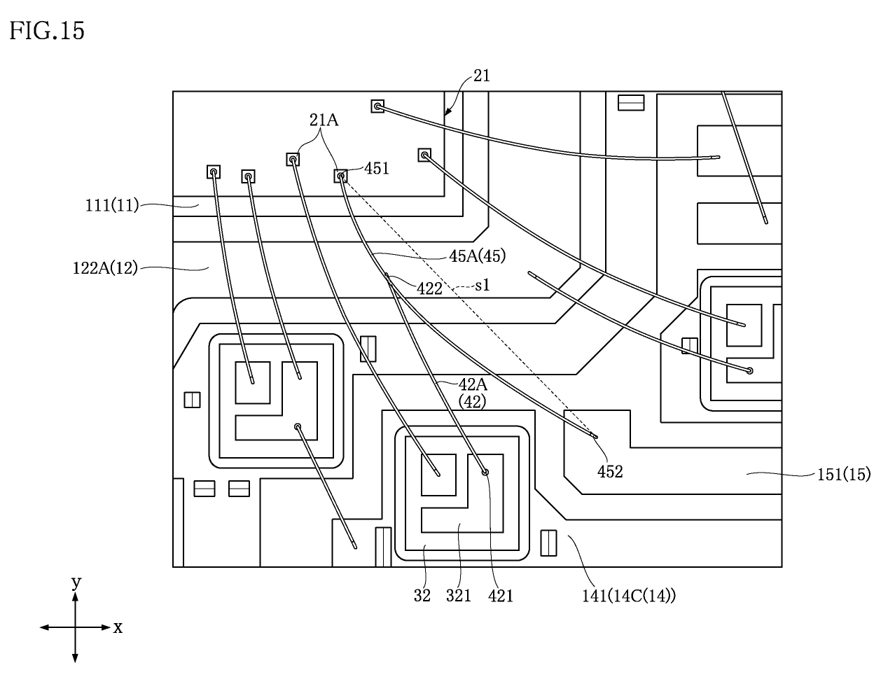

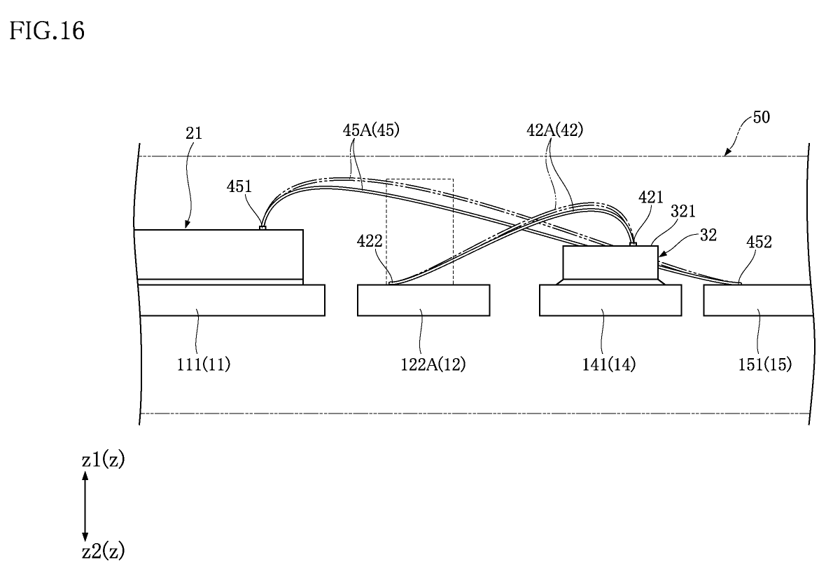

FIG. 1 is a perspective view of the semiconductor device A10. FIGS. 2 and 3 are plan views of the semiconductor device A10. For convenience of description, FIG. 3 shows the sealing resin 50 as being transparent and represents the outline of the sealing resin 50 in a phantom line (dash-double dot line). FIG. 4 is a front view of the semiconductor device A10. FIG. 5 is a rear view of the semiconductor device A10. FIG. 6 is a right-side view of the semiconductor device A10. FIG. 7 is a left-side view of the semiconductor device A10. FIG. 8 is a sectional view taken along line VIII-VIII in FIG. 3. FIG. 9 is a sectional view taken along line IX-IX in FIG. 3. FIG. 10 is a sectional view taken along line X-X in FIG. 3. FIG. 11 is a sectional view taken along line XI-XI in FIG. 3. FIG. 12 is a sectional view taken along line XII-XII in FIG. 3. FIG. 13 is an enlarged partial sectional view taken along line XIII-XIII in FIG. 3. FIG. 14 is an enlarged partial sectional view taken along line XIV-XIV in FIG. 3. FIG. 15 is an enlarged partial view of FIG. 3. FIG. 16 is a lateral view showing the arrangement of a first wire 42A and a second wire 45A, which will be described later.

With reference to these figures, the “thickness direction z” is one example of the thickness direction recited in the present disclosure. Additionally, one side along the thickness direction z is defined as the “first side in the thickness direction” recited in the present disclosure and is referred to as “z1 side in the thickness direction z”. The opposite side along the thickness direction z is defined as the “second side in the thickness direction” recited in the present disclosure and is referred to “z2 side in the thickness direction z”. A direction perpendicular to the thickness direction z is defined as the “first direction x”. The “first side in the first direction x” refers to the side along the first direction x, faced by the right side surface of the semiconductor device A10 (the side surface shown in FIG. 6). The “second side in the first direction x” refers to the opposite side along the first direction x, faced by the left side surface of the semiconductor device A10 (the side surface shown in FIG. 7). The direction perpendicular to both the thickness direction z and the first direction x is referred to as the “second direction y.”

The semiconductor device A10 converts direct current (DC) power into three-phase alternating current (AC) power using the first switching elements 31 and the second switching elements 32. For example, the semiconductor device A10 is used to control the operation of a brushless DC motor.

The first lead 11, the second lead 12, the third lead 13, the fourth leads 14, the fifth leads 15, and the sixth leads 16 are conductive members fabricated from a single lead frame. These conductive members form part of a conductive path connecting the respective elements (the drive element 21, the control element 22, the first switching elements 31, and the second switching elements 32) to a wiring board on which the semiconductor device A10 is mounted. The lead frame is made of, for example, copper (Cu) or a copper alloy.

As shown in FIG. 3, the first lead 11 includes a mounting portion 111, a first terminal portion 112, a first connecting portion 113, and a first suspension portion 114.

As shown in FIG. 3, the mounting portion 111 extends in the first direction x. As viewed in the thickness direction z, the mounting portion 111 has a rectangular shape elongated in the first direction x. As shown in FIGS. 8 and 9, the mounting portion 111 includes an obverse surface 111A facing the thickness direction z. In the example shown in the figure, the obverse surface 111A is perpendicular to the thickness direction z. The obverse surface 111A may be covered with, for example, silver (Ag) plating.

As shown in FIGS. 2 and 3, the first terminal portion 112 protrudes from the sealing resin 50 toward the second side in the first direction x (leftward in the figure) as viewed in the thickness direction z. The first terminal portion 112 is bent at, for example, two locations as viewed in the second direction y. The first terminal portion 112 is covered with, for example, tin (Sn) plating or tin-silver alloy plating.

As shown in FIG. 3, the first connecting portion 113 connects the mounting portion 111 and the first terminal portion 112. The first connecting portion 113 includes a region 113A inclined relative to both the first direction x and the second direction y. The surface of the first connecting portion 113 (the surface facing the same side as the obverse surface 111A) may be covered with, for example, silver plating.

As shown in FIG. 3, the first suspension portion 114 is positioned opposite the first connecting portion 113 with respect to the mounting portion 111 in the second direction y. The first suspension portion 114 extends in the second direction y. The mounting portion 111 is positioned between the first connecting portion 113 and the first suspension portion 114 in the second direction y. The first suspension portion 114 includes an end face 114A facing the second direction y and exposed from the sealing resin 50 (see FIG. 5). In FIG. 3, the first suspension portion 114 and the first connecting portion 113 are spaced apart from a pair of second band-shaped portions 122A and 122B (described later) of the second lead 12 to the left (in a direction away from a first band-shaped portion 121 of the second lead 12).

As shown in FIG. 3, the second lead 12 is spaced apart from the first lead 11 and extends along the outer edge of the first lead 11. In the example shown in the figure, the second lead 12 is generally positioned on one side (the right-hand side in the figure) with respect to the first lead 11. The second lead 12 includes the first band-shaped portion 121, the pair of second band-shaped portions 122A and 122B, a second terminal portion 123, a second connecting portion 124, a second suspension portion 125, and a second auxiliary suspension portion 126.

As shown in FIG. 3, the first band-shaped portion 121 is positioned on the first side in the first direction x (the right-hand side in the figure) with respect to the mounting portion 111. The first band-shaped portion 121 extends in the second direction y. As shown in FIG. 9, the mounting portion 111 overlaps with the first band-shaped portion 121 as viewed in the first direction x. In other words, the mounting portion 111 and the first band-shaped portion 121 are at the same height (or substantially the same height) above the bottom surface of the sealing resin 50, for example.

As shown in FIG. 3, the second band-shaped portions 122A and 122B extend from the opposite ends of the first band-shaped portion 121 toward the second side in the first direction x (leftward in the figure). As viewed in the thickness direction z, the second band-shaped portions 122A and 122B are perpendicular to the first band-shaped portion 121. At least a portion of the mounting portion 111 is positioned between the second band-shaped portions 122A and 122B. The respective surfaces of the first band-shaped portion 121 and the second band-shaped portions 122A and 122B may be covered with, for example, silver plating.

As shown in FIGS. 2 and 3, the second terminal portion 123 protrudes from the sealing resin 50 toward the second side in the first direction x (leftward in the figure) as viewed in the thickness direction z. As shown in FIG. 4, the second terminal portion 123 is bent at, for example, two locations as viewed in the second direction y. The second terminal portion 123 is adjacent to the first terminal portion 112 in the second direction y. The second terminal portion 123 is covered with, for example, tin plating or tin-silver alloy plating.

As shown in FIG. 3, the second connecting portion 124 connects the second band-shaped portion 122A and the second terminal portion 123. The second connecting portion 124 is positioned on the second side in the first direction x (the left-hand side in the figure) with respect to the pair of second band-shaped portions 122A and 122B. In the second direction y, the second connecting portion 124 is adjacent to the first connecting portion 113. The second connecting portion 124 includes a region 124A inclined relative to both the first direction x and the second direction y. The surface of the second connecting portion 124 may be covered with, for example, silver plating.

As shown in FIG. 3, the second suspension portion 125 extends from the second band-shaped portion 122B in the second direction y. At least a portion of the second suspension portion 125 is positioned to the left of the pair of second band-shaped portions 122A and 122B in the first direction x. The second suspension portion 125 is adjacent to the first suspension portion 114 in the first direction x. The second suspension portion 125 includes an end face 125A facing the second direction y and exposed from the sealing resin 50 (see FIG. 5).

As shown in FIG. 3, the second connecting portion 124 includes a portion parallel to the first direction x, and the second auxiliary suspension portion 126 extends therefrom in the second direction y. The second auxiliary suspension portion 126 includes an end face 126A facing the second direction y and exposed from the sealing resin 50 (see FIG. 4).

As shown in FIG. 3, the third lead 13 is positioned on the first side in the first direction x (the right-hand side in the figure) with respect to the second lead 12. The third lead 13 includes a plurality of first pad portions 130, a third terminal portion 132, a third connecting portion 133, a third suspension portion 134 and a third auxiliary suspension portion 135. In the example shown in the figure, three first pad portions 130 are provided.

As shown in FIG. 3, each first pad portion 130 has a first switching element 31 electrically bonded thereto. As shown in FIG. 8, 9, and 13, each first pad portion 130 has an obverse surface 130A facing the upper side (the direction in which the obverse surface 111A of the mounting portion 111 faces along the thickness direction z). The obverse surface 130A may be covered with, for example, silver plating. The first pad portions 130 include a plurality of regions, which are a first region 131A, a second region 131B, and a third region 131C in the example shown in FIG. 3.

As shown in FIG. 3, the first region 131A is positioned close to the second suspension portion 125. At least a portion of the first region 131A is adjacent to the second suspension portion 125 in the first direction x. In the second direction y, the first region 131A is adjacent to the second band-shaped portion 122B. As shown in FIGS. 3 and 9, the first region 131A is provided with a pair or holes 130B that penetrates the first region 131A in the thickness direction z. The holes 130B are spaced apart from each other in the second direction y, with the first switching element 31 interposed between them. As shown in FIGS. 3 and 13, the first region 131A is formed with a plurality of grooves 130C that are recessed from the obverse surface 130A. These grooves 130C are spaced apart from each other around the first switching element 31. The grooves 130C may be formed, for example, by V-notch processing. Similar to other grooves (described later), the grooves 130C serve to dam up solder used to bond the first switching element 31 to the first region 131A.

As shown in FIG. 3, the second region 131B is adjacent to the first band-shaped portion 121 of the second lead 12 in the first direction x. The second region 131B is formed with a groove 130C. The groove 130C is positioned on the first side in the first direction x (the right-hand side in the figure) with respect to the first switching element 31.

As shown in FIG. 3, the third region 131C is adjacent to the second connecting portion 124 of the second lead 12 in the first direction x. In the second direction y, the third region 131C is adjacent to the second band-shaped portion 122A of the second lead 12. The third region 131C is formed with a groove 130C. The groove 130C is positioned on the second side in the first direction x (the left-hand side in the figure) with respect to the first switching element 31.

As shown in FIGS. 2 and 3, the third terminal portion 132 protrudes from the sealing resin 50 toward the first side in the first direction x (rightward in the figure) as viewed in the thickness direction z. As shown in FIG. 5, the third terminal portion 132 is bent as viewed in the second direction y. The third terminal portion 132 is covered with, for example, tin plating or tin-silver alloy plating.

As shown in FIG. 3, the third connecting portion 133 connects the first pad portions 130 and the third terminal portion 132. The third connecting portion 133 includes an outer connecting portion 133A, a first inner connecting portion 133B, and a second inner connecting portion 133C.

As shown in FIG. 3, the outer connecting portion 133A connects the first region 131A and the third terminal portion 132. The outer connecting portion 133A extends in the first direction x.

As shown in FIG. 3, the first inner connecting portion 133B connects the first region 131A and the second region 131B. The first inner connecting portion 133B is provided with a groove 133D at the end connected to the second region 131B. The groove 133D is recessed from the surface of the third connecting portion 133. The groove 133D is formed by the same method as the grooves 130C.

As shown in FIG. 3, the second inner connecting portion 133C connects the second region 131B and the third region 131C. The second inner connecting portion 133C is provided with grooves 133D, one at the end connected to the third region 131C, and another at the end connected to the second region 131B.

As shown in FIG. 3, the second region 131B includes a portion protruding farther toward the first side in the first direction x (rightward in the figure) than the first inner connecting portion 133B and the second inner connecting portion 133C.

As shown in FIG. 3, the third suspension portion 134 extends from the third region 131C in the second direction y. The third suspension portion 134 includes an end face 134A facing the second direction y and exposed from the sealing resin 50 (see FIG. 4). The end face 134A includes two regions spaced apart from each other in the first direction x. The third suspension portion 134 is provided with a plurality of grooves 134B at the end connected to the third region 131C. The grooves 134B are recessed from the surface of the third suspension portion 134. The grooves 134B are formed by the same method as the grooves 130C.

As shown in FIG. 3, the third auxiliary suspension portion 135 extends from the outer connecting portion 133A in the second direction y. The third auxiliary suspension portion 135 includes an end face 135A facing the second direction y and exposed from the sealing resin 50 (see FIG. 5).

As shown in FIG. 10 as viewed in the first direction x, the first band-shaped portion 121 overlaps with the second region 131B, the first inner connecting portion 133B, and the second inner connecting portion 133C. As shown in FIG. 3, each of the second band-shaped portions 122A and 122B includes a portion positioned between the first inner connecting portion 133B and the second inner connecting portion 133C.

As shown in FIG. 3, the fourth leads 14 are positioned on the first side in the first direction x (right-hand side in the figure) with respect to the third lead 13. Each fourth lead 14 includes a second pad portion 141 and a fourth terminal portion 142.

As shown in FIG. 3, each second pad portion 141 has a second switching element 32 electrically bonded thereto. Each second pad portion 141 includes an obverse surface 141A facing the upper side (the direction in which the obverse surface 111A of the mounting portion 111 faces along the thickness direction z). The obverse surface 141A may be covered with, for example, silver plating.

As shown in FIGS. 2 and 3, each fourth terminal portion 142 protrudes from the sealing resin 50 toward the first side in the first direction x (rightward in the figure) as viewed in the thickness direction z. Each fourth terminal portion 142 is continuous with the corresponding second pad portion 141. The fourth terminal portions 142 are aligned in the second direction y, along with the third terminal portion 132. As with the first to third terminal portions, each fourth terminal portion 142 is bent as viewed in the second direction y (see FIGS. 4 and 5). Each fourth terminal portion 142 is covered with, for example, tin plating or tin-silver alloy plating.

As shown in FIG. 3, the fourth leads 14 include a U-phase lead 14A, a V-phase lead 14B, and a W-phase lead 14C.

As shown in FIG. 11, the second pad portion 141 of the U-phase lead 14A partly overlaps with the first region 131A as viewed in the first direction x. The second pad portion 141 of the U-phase lead 14A is partly positioned between the outer connecting portion 133A and the first inner connecting portion 133B. As shown in FIGS. 3 and 12, the second pad portion 141 of the U-phase lead 14A is provided with a hole 141B that penetrates the second pad portion 141 in the thickness direction z. The hole 141B is positioned on the first side in the first direction x (the right-hand side in the figure) with respect to the second switching element 32. As shown in FIGS. 3 and 14, the second pad portion 141 of the U-phase lead 14A is provided with a plurality of grooves 141C that are recessed from the obverse surface 141A. The grooves 141C are positioned around the second switching element 32. The grooves 141C are formed by the same method as the grooves 130C.

As shown in FIG. 3, the second pad portion 141 of the V-phase lead 14B is adjacent to the second inner connecting portion 133C in the first direction x. The second pad portion 141 of the V-phase lead 14B is formed with a plurality of grooves 141C. The grooves 141C are positioned around the second switching element 32.

As shown in FIG. 3, the second pad portion 141 of the W-phase lead 14C is adjacent to both the third region 131C and the third suspension portion 134 in the first direction x. In the second direction y, the second pad portion 141 of the W-phase lead 14C is adjacent to the second inner connecting portion 133C. The second pad portion 141 of the W-phase lead 14C is formed with a plurality of grooves 141C. The grooves 141C are positioned around the second switching element 32.

As shown in FIG. 3, the fifth leads 15 are positioned on the first side in the first direction x (right-hand side in the figure) with respect to the third lead 13. Each fifth lead 15 is adjacent to a fourth lead 14 in the second direction y. Each fifth lead 15 includes a connection portion 151 and a fifth terminal portion 152.

As shown in FIG. 3, at least a portion of each connection portion 151 is adjacent to the second pad portion 141 in the second direction y. The surface of each connection portion 151 (the surface facing the same side as the obverse surface 111A of the mounting portion 111in the thickness direction z) may be covered with, for example, silver plating.

As shown in FIGS. 2 and 3, each fifth terminal portion 152 protrudes from the sealing resin 50 toward the first side in the first direction x (rightward in the figure) as viewed in the thickness direction z. Each fifth terminal portion 152 is continuous with the corresponding connection portion 151. The fifth terminal portions 152 are aligned in the second direction y, along with the third terminal portion 132 and the fourth terminal portions 142. As with the first to fourth terminal portions, each fifth terminal portion 152 is bent as viewed in the second direction y. Each fifth terminal portion 152 is covered with, for example, tin plating or tin-silver alloy plating.

As shown in FIG. 3, the sixth leads 16 are positioned on the second side in the first direction x (left-hand side in the figure) with respect to the first lead 11. Each sixth lead 16 includes a connection portion 161 and a sixth terminal portion 162.

As shown in FIG. 3, the mounting portion 111 includes a portion protruding further toward the second side in the first direction x (leftward in the figure) than the region 113A of the first connecting portion 113 and the first suspension portion 114. The connection portions 161 are spaced apart from one another along a substantially arc-shaped line (or a polygonal line) and extend to a position facing the protruding portion of the mounting portion 111. The surface of each connection portion 161 may be covered with, for example, silver plating.

As shown in FIGS. 2 and 3, each sixth terminal portion 162 protrudes from the sealing resin 50 toward the second side in the first direction x (leftward in the figure) as viewed in the thickness direction z. Each sixth terminal portion 162 is continuous with the corresponding connection portion 161. The sixth terminal portions 162 are aligned in the second direction y, along with the first terminal portion 112 and the second terminal portion 123. As with the other terminal portions, each sixth terminal portion 162 is bent as viewed in the second direction y as shown in FIG. 5. Each sixth terminal portion 162 is covered with, for example, tin plating or tin-silver alloy plating.

As shown in FIGS. 3, 8, and 9, the drive element 21 is mounted on the mounting portion 111. As shown in FIGS. 8 and 9, the drive element 21 is bonded to the obverse surface 111A of the mounting portion 111 via a bonding layer 29. The bonding layer 29 is, for example, a silver paste containing an epoxy resin as the main component. The drive element 21 outputs a gate voltage for driving the first switching elements 31 and the second switching elements 32. In the semiconductor device A10, the drive element 21 has a band-shape extending in the first direction x as viewed in the thickness direction z. A plurality of electrodes 21A are disposed on the upper surface (the surface on the z1 side in the thickness direction z) of the drive element 21. The electrodes 21A include those electrically connected to the first switching elements 31 and those electrically connected to the second switching elements 32. Other electrodes 21A are electrically connected to the first lead 11, the fifth leads 15, or the sixth lead 16. The electrodes 21A are made of, for example, aluminum (Al). Although the dimension of the drive element 21 in the thickness direction z is not particularly limited, it may be about 400 µm, for example.

As shown in FIGS. 3 and 8, the control element 22 is mounted on the mounting portion 111 and is positioned on the second side in the first direction x (left-hand side in the figure) with respect to the drive element 21. The control element 22 is bonded to the obverse surface 111A of the mounting portion 111 via a bonding layer 29. The control element 22 controls the drive element 21. A plurality of electrodes 22A are disposed on the upper surface (the surface on the z1 side in the thickness direction z) of the control element 22. The electrodes 22A include those electrically connected to some of the electrodes 21A of the drive element 21. Other electrodes 22A are electrically connected to the first lead 11 or the sixth leads 16. The electrodes 22A are made of, for example, aluminum.

As shown in FIGS. 3, 8, and 9, the first switching elements 31 are electrically bonded to the respective obverse surfaces 130A of the first pad portions 130 (the third lead 13). Thus, in the semiconductor device A10, one first switching element 31 is electrically bonded to each of the first region 131A, the second region 131B, and the third region 131C. The first switching elements 31 are electrically connected to the respective second pad portions 141 (the fourth leads 14). The first switching elements 31 are MOSFETs (metal-oxide-semiconductor field-effect transistors) mainly composed of silicon (Si) or silicon carbide (SiC). The first switching elements 31 may be semiconductor elements other than MOSFETs. The semiconductor device A10 will be described for a case in which the first switching element 31 is an n‑channel MOSFET. As shown in FIG. 13, each first switching element 31 includes a first element obverse surface 31A, a first element reverse surface 31B, a first obverse-surface electrode 311, a first reverse-surface electrode 312, and a first gate electrode 313. The first element obverse surface 31A and the first element reverse surface 31B face away from each other in the thickness direction z. The first element obverse surface 31A faces the z1 side in the thickness direction z, while the first element reverse surface 31B faces the z2 side in the thickness direction z.

As shown in FIGS. 3 and 13, the first obverse-surface electrode 311 is disposed on the first element obverse surface 31A. The first obverse-surface electrode 311 corresponds to the source electrode of the first switching element 31.

As shown in FIG. 13, the first reverse-surface electrode 312 covers the entire first element reverse surface 31B. The first reverse-surface electrode 312 corresponds to the drain electrode of the first switching element 31.

As shown in FIGS. 3 and 13, the first gate electrode 313 is disposed on the first element obverse surface 31A. The first gate electrode 313 corresponds to the gate electrode of the first switching element 31. As viewed in the thickness direction z, the first gate electrode 313 has a smaller area than the first obverse-surface electrode 311. Although the dimension of the first switching elements 31 in the thickness direction z, as well as that of and the second switching elements 32 described later, is not particularly limited, it may be about 270 μm, for example.

As shown in FIGS. 3, 10, and 12, the second switching elements 32 are electrically bonded to the respective obverse surfaces 141A of the second pad portions 141 (the fourth lead 14). Thus, in the semiconductor device A10, one second switching element 32 is electrically bonded to each of the U-phase lead 14A, the V-phase lead 14B, and the W-phase lead 14C. The second switching elements 32 are electrically connected to the second lead 12. The second switching elements 32 are the same type of semiconductor elements as the first switching elements 31. As shown in FIG. 14, each second switching element 32 includes a second element obverse surface 32A, a second element reverse surface 32B, a second obverse-surface electrode 321, a second reverse-surface electrode 322, and a second gate electrode 323. The second element obverse surface 32A and the second element reverse surface 32B face away from each other in the thickness direction z. The second element obverse surface 32A faces the z1 side in the thickness direction z, while the second element reverse surface 32B faces the z2 side in the thickness direction z.

As shown in FIGS. 3 and 14, the second obverse-surface electrode 321 is disposed on the second element obverse surface 32A. The second obverse-surface electrode 321 corresponds to the source electrode of the second switching element 32.

As shown in FIG. 14, the second reverse-surface electrode 322 covers the entire second element reverse surface 32B. The second reverse-surface electrode 322 corresponds to the drain electrode of the second switching element 32.

As shown in FIGS. 3 and 14, the second gate electrode 323 is disposed on the second element obverse surface 32A. The second gate electrode 323 corresponds to the gate electrode of the second switching element 32. As viewed in the thickness direction z, the second gate electrode 323 has a smaller area than the second obverse-surface electrode 321.

As shown in FIGS. 8 to 14, the semiconductor device A10 includes a plurality of conductive bonding layers 39. Some of the conductive bonding layers 39 are individually disposed between the obverse surfaces 130A of the first pad portions 130 and the first reverse-surface electrodes 312 of the first switching elements 31. Other conductive bonding layers 39 are individually disposed between the obverse surfaces 141A of the second pad portions 141 and the second reverse-surface electrodes 322 of the second switching elements 32. The first switching elements 31 are electrically bonded to the obverse surfaces 130A via the relevant conductive bonding layers 39. Thus, the first reverse-surface electrodes 312 are electrically connected to the third lead 13. The second switching elements 32 are electrically bonded to the obverse surfaces 141A via the relevant conductive bonding layers 39. Thus, the second reverse-surface electrodes 322 are electrically connected to the fourth leads 14. The conductive bonding layers 39 are made of, for example, lead-free solder mainly composed of tin.

As shown in FIG. 3, the wires 41 are individually bonded to the first obverse-surface electrodes 311 of the first switching elements 31 and to the second pad portions 141. Thus, the fourth leads 14 are electrically connected to the first switching elements 31 via the wires 41. Examples of the material of the wires 41 include gold (Au), copper, silver, and aluminum.

As shown in FIG. 3, the wires 42 are individually bonded to the second obverse-surface electrodes 321 of the second switching elements 32 and to the second lead 12 (the pair of second band-shaped portions 122A and 122B). Thus, the second switching elements 32 are electrically connected to the second lead 12 via the wires 42. Examples of the material of the wires 42 include gold, copper, silver, and aluminum.

As shown in FIG. 3, each of the wires 431, the wires 432, the wires 441, the wire 442, and the wires 45 is connected to one electrode 21A of the drive element 21. Each of the wires 46 and the wires 47 is connected to one electrode 21A of the drive element 21 or to one electrode 22A of the control element 22. Examples of the material of these wires include gold, copper, silver, and aluminum.

The following describes a case where the wires 41, the wires 42, the wires 431, the wires 432, the wires 441, the wire 442, and the wires 45, the wires 46, and the wires 47 are all made of gold. In this case, the respective diameters of the wires 41, 42, 431, 432, 441, 442, 45, 46, and 47 are the same (or substantially the same). Unlike the above configuration, when all of the wires are made of aluminum, the diameters of the wires 41 and 42 are set to be larger than those of the wires 431, 432, 441, 442, 45, 46, and 47, for the following reason. That is, in the semiconductor device A10, the current that flows through the wires 41 and 42 is greater than the current that flows through the other wires. Note that the wires of the semiconductor device A10 may all be made of the same material or of different materials.

As shown in FIG. 3, the wires 431 are individually connected to the electrodes 21A of the drive element 21 and to the first gate electrodes 313 of the first switching elements 31. Thus, the first gate electrodes 313 are electrically connected to the drive element 21 via the wires 431. The gate voltage that is output from the drive element 21 is applied individually to each of the first gate electrodes 313 via the corresponding wire 431.

As shown in FIG. 3, the wires 432 are individually connected to the electrodes 21A of the drive element 21 and to the second gate electrodes 323 of the second switching elements 32. Thus, the second gate electrodes 323 are electrically connected to the drive element 21 via the wires 432. The gate voltage that is output from the drive element 21 is applied individually to each of the second gate electrodes 323 via the corresponding wire 432.

As shown in FIG. 3, the wires 441 are individually connected to the electrodes 21A of the drive element 21 and to the first obverse-surface electrodes 311 of the first switching elements 31. Thus, the first obverse-surface electrodes 311 are electrically connected to the drive element 21 via the wires 441. The first obverse-surface electrodes 311 are electrically connected to the fourth lead 14. The negative potential of the gate power supply that generates the gate voltage for driving the first switching elements 31 differs for each of the first switching elements 31. Additionally, this gate voltage is required to be higher than the gate voltage for driving the second switching elements 32. In view of this, the gate power supply that generates the gate voltage includes a plurality of capacitors electrically connected to the semiconductor device A10. The capacitors correspond to the respective first switching elements 31. The negative potential of each capacitor is transmitted to the drive element 21 via the corresponding wire 441.

As shown in FIG. 3, the wire 442 is connected to an electrode 21A of the drive element 21 and to the second lead 12. The second obverse-surface electrodes 321 of the second switching elements 32 are electrically connected to the drive element 21 via the wires 42, the second lead 12, and the wire 442. The wire 442 transmits the potential at the second obverse-surface electrodes 321 of the second switching elements 32 to the drive element 21. The source current that flows from the second switching elements 32 is sensed by the drive element 21 via the wire 442.

As shown in FIG. 3, the wires 45 are individually connected to the electrodes 21A of the drive element 21 and to the connection portions 151. Thus, the fifth leads 15 are electrically connected to the drive element 21 via the wires 45.

In the example shown in FIG. 3, four wires 46 are provided. One of the wires 46 is connected to one electrode 21A of the drive element 21 and to the first connecting portion 113. The other three wires 46 are each connected to one electrode 22A of the control element 22 and to the first connecting portion 113. Thus, the first lead 11 is electrically connected to both the drive element 21 and the control element 22 via the wires 46.

As shown in FIG. 3, the wires 47 are classified into three groups according to their connection targets. The first group includes wires 47 each of which connects one electrode 22A of the control element 22 to a corresponding connection portion 161. The second group includes wires 47 each of which connects one electrode 22A of the control element 22 to a corresponding electrode 21A of the drive element 21. The third group includes wires 47 each of which connects one electrode 21A of the drive element 21 to a corresponding connection portion 161.

As shown in FIG. 3, the sealing resin 50 covers a portion of each of the first lead 11, the second lead 12, the third lead 13, the fourth leads 14, the fifth leads 15, and the sixth leads 16. As shown in FIG. 3, the sealing resin 50 also covers the drive element 21, the control element 22, the first switching elements 31, and the second switching elements 32. The sealing resin 50 is made of, for example, a black epoxy resin. As shown in FIGS. 2 and 4 to 7, the sealing resin 50 includes a pair of first side surfaces 51A and 51B and a pair of second side surfaces 52A and 52B.

As shown in FIGS. 2, 6, and 7, the first side surfaces 51A and 51B are spaced apart from each other in the first direction x. The first side surface 51A faces the first side in the first direction x (the right-hand side in FIG. 2), whereas the first side surface 51B faces the second side in the first direction x (the left-hand side in FIG. 2). The third terminal portion 132, the fourth terminal portions 142, and the fifth terminal portion 152 protrude from the first side surface 51A toward the first side in the first direction x (rightward in FIG. 2) as viewed in the thickness direction z. In contrast, the first terminal portion 112 the second terminal portion 123, and the sixth terminal portions 162 protrude from the first side surface 51B toward second side in the first direction x (leftward in FIG. 2) as viewed in the thickness direction z.

As shown in FIGS. 2, 4, and 5, the second side surfaces 52A and 52B are spaced apart from each other in the second direction y. In FIG. 2, the second side surface 52A faces upward, and the second side surface 52B faces downward. As shown in FIG. 5, the end face 114A of the first suspension portion 114, the end face 125A of the second suspension portion 125, and the end face 135A of the third auxiliary suspension portion 135 are exposed at the second side surface 52A. As shown in FIG. 4, the end face 126A of the second auxiliary suspension portion 126, the end face 134A of the third suspension portion 134, and the end face 141D of the second pad portion 141 (the W-phase lead 14C) are exposed at the second side surface 52B.

In the manufacture of the semiconductor device A10, the sealing resin 50 is formed by injecting molten resin into a mold cavity and then solidifying the resin. The flow of resin during the resin injection may cause deformation of the wire loops, resulting in wire sweep. Specifically, during the manufacture of the semiconductor device A10, the resin flows from the upper side to the lower side in FIG. 3 (from the first side to the second side in the second direction y). This may cause the wires 41, 42, 431, 432, 441, 442, 45, 46, and 47 to undergo wire sweep. Each wire as bonded appears straight as viewed in the thickness direction z. During the molding of the sealing resin 50, however, if wire sweep occurs, the affected wires are curved into a convex shape toward the lower side in FIG. 3 as viewed in the thickness z direction. The extent to which the wire loops are deformed by the resin injection may vary depending on the length of each wire or the orientation of each wire as viewed in the thickness direction z. Longer wires are more prone to wire sweep.

As shown in FIGS. 3, 15, and 16, in the semiconductor device A10, the wires 42 include one first wire 42A, and the wires 45 include one second wire 45A. The first wire 42A and the second wire 45A are adjacent to each other. FIG. 16 is a lateral view schematically showing the arrangement of the first wire 42A and the second wire 45A. For convenience of description, FIG. 16 shows the sealing resin 50 as being transparent and represents the outline of the sealing resin 50 in a phantom line.

The first wire 42A has a first end portion 421 and a second end portion 422. The first end portion 421 is at one end of the first wire 42A and is bonded to the surface of the second switching element 32 positioned on the z1 side in the thickness direction z (to the second obverse-surface electrode 321 disposed on the second element obverse surface 32A). The second end portion 422 is at the opposite end of the first wire 42A and is bonded to the second band-shaped portion 122A of the second lead 12. As shown in FIG. 16, the first end portion 421 is located above the second end portion 422 (toward the z1 side in the thickness direction z). The first end portion 421 corresponds to the first bonding portion, and the first wire 42A forms a loop shape that rises from the first end portion 421 and gently descends toward the second end portion 422. The second switching element 32 to which the first end portion 421 is bonded is an example of the “first element” recited in the present disclosure.

The second wire 45A has a third end portion 451 and a fourth end portion 452. The third end portion 451 is at one end of the second wire 45A and is bonded to an electrode 21A disposed on a surface of the drive element 21 on the z1 side in the thickness direction z. The fourth end portion 452 is at the opposite end of the second wire 45A and is bonded to the connection portion 151 of a fifth lead 15. As shown in FIG. 16, the third end portion 451 is located above the fourth end portion 452 (toward the z1 side in the thickness direction z). The third end portion 451 corresponds to the first bonding portion, and the second wire 45A forms a loop shape that rises from the third end portion 451 and gently descends toward the fourth end portion 452. The drive element 21 to which the third end portion 451 is bonded is an example of the “second element” recited in the present disclosure.

In the present embodiment, the total length of the second wire 45A is longer than that of the first wire 42A. As shown in FIG. 15, the third end portion 451 of the second wire 45A is positioned closer to the second end portion 422 of the first wire 42A than to the first end portion 421. The fourth end portion 452 of the second wire 45A is positioned closer to the first end portion 421 of the first wire 42A than to the second end portion 422.

As shown in FIG. 15, the second wire 45A is curved by wire sweep into a convex shape toward the first wire 42A as viewed in the thickness direction z. The second wire 45A extends across the first wire 42A as viewed in the thickness direction z. In the example shown in the figure, the second wire 45A extends across the second end portion 422 of the first wire 42A. In contrast, a line segment s1 connecting the third end portion 451 and the fourth end portion 452 does not intersect the first wire 42A as viewed in the thickness direction z. That is, prior to molding of the sealing resin 50, the second wire 45A does not intersect the first wire 42A as viewed in the thickness direction z.

As described above, the second wire 45A extends across the first wire 42A as viewed in the thickness direction z. As shown in FIG. 16, however, the second wire 45A is spaced apart from the first wire 42A in the thickness direction z. In FIG. 16, the first wire 42A and the second wire 45A prior to molding of the sealing resin 50 are represented by dash-double dot lines. As a result of molding of the sealing resin 50, the first wire 42A and the second wire 45A are displaced by wire sweep toward the z2 side in the thickness direction z, as compared with their positions before molding of the sealing resin 50. The first wire 42A and the second wire 45A after molding of the sealing resin 50 are indicated by a solid line. Although the second wire 45A is curved by wire sweep into a convex shape toward the first wire 42A as viewed in the thickness direction z, the second wire 45A remains spaced apart from the first wire 42A in the thickness direction z as shown in FIG. 16. In FIG. 16, a region bounded by a dotted line indicates a portion in which wire sweep may cause the second wire 45A to extend across the first wire 42A as viewed in the thickness direction z. As can be seen from FIGS. 15 and 16, in the portion in which the second wire 45A may extend across the first wire 42A as viewed in the thickness direction z, a sufficient spacing is provided between the second wire 45A and the first wire 42A in the thickness direction z.

In the present embodiment, as is clear from FIG. 16, the dimension of the drive element 21 in the thickness direction z is greater than the dimension of the second switching element 32 in the thickness direction z. Thus, the third end portion 451, which is bonded to the surface of the drive element 21 on the z1 side in the thickness direction z, is positioned on the z1 side in the thickness direction z with respect to the first end portion 421, which is bonded to the surface of the second switching element 32 on the z1 side in the thickness direction z.

In the semiconductor device A10, DC power for driving the motor to be controlled is input via the third terminal portion 132. The DC power supplied to the third terminal portion 132 flows through the first switching elements 31, the wires 41, the second switching elements 32, and the wires 42, and then exits via the second terminal portion 123.

The DC power supplied to the semiconductor device A10 is converted into three-phase AC power in U-, V- and W-phases through operation of the first switching elements 31 and the second switching elements 32. The U-phase AC power is output via the fourth terminal portion 142 of the U-phase lead 14A. The V-phase AC power is output via the fourth terminal portion 142 of the V-phase lead 14B. The W-phase AC power is output via the fourth terminal portion 142 of the W-phase lead 14C. The three-phase A power output via the fourth terminal portions 142 drives the motor.

### The following describes effects of the semiconductor device A10.

In the present embodiment, the second wire 45A is curved into a convex shape toward the first wire 42A as viewed in the thickness direction z. The second wire 45A extends across the first wire 42A as viewed in the thickness direction z. The second wire 45A is spaced apart from the first wire 42A in the thickness direction z. With this configuration, even if the second wire 45A undergoes wire sweep during molding of the sealing resin 50, contact between the adjacent first wire 42A and second wire 45A can be avoided. As a result, the semiconductor device A10 can appropriately maintain its electrical function.

The first end portion 421 of the first wire 42A is bonded to the surface of the second switching element 32 (the first element) on the z1 side in the thickness direction z. The third end portion 451 of the second wire 45A is bonded to the surface of the drive element 21 (the second element) on the z1 side in the thickness direction z. The third end portion 451 of the second wire 45A is positioned closer to the second end portion 422 of the first wire 42A than to the first end portion 421. The fourth end portion 452 of the second wire 45A is positioned closer to the first end portion 421 of the first wire 42A than to the second end portion 422. This configuration ensures, as shown in FIG. 16, that the first wire 42A and the second wire 45A, which are adjacent to each other, have opposite loop directions. That is, in the region where the second wire 45A may extend across the first wire 42A as viewed in the thickness direction z, the second wire 45A is at a sufficient distance from the first wire 42A in the thickness direction z. Thus, undesirable contact between the first wire 42A and the second wire 45A is reliably prevented.

The third end portion 451 is bonded to the surface of the drive element 21 on the z1 side in the thickness direction z and thus is positioned on the z1 side in the thickness direction z with respect to the first end portion 421, which is bonded to the surface of the second switching element 32 on the z1 side in the thickness direction z. Although the second wire 45A may extend across the first wire 42A as viewed in the thickness direction z, this configuration provides a greater distance between the first wire 42A and the second wire 45A in the thickness direction z.

### First Variation of First Embodiment:

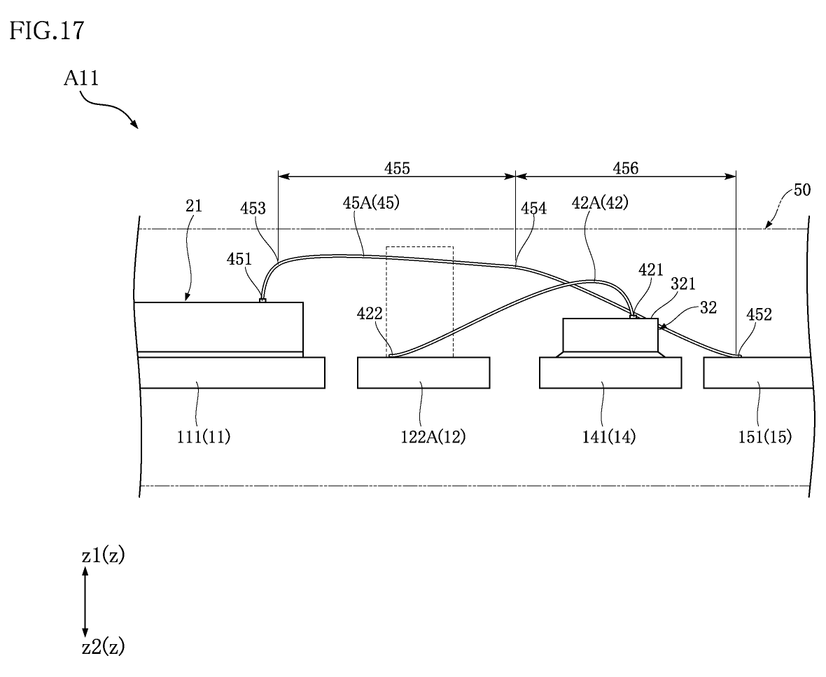

FIG. 17 shows a semiconductor device according to a first variation of the first embodiment. FIG. 17 is a lateral view of a semiconductor device A11 according to this variation, schematically showing the arrangement of a first wire 42A and a second wire 45A. For convenience of description, FIG. 17 shows the sealing resin 50 as being transparent and represents the outline of the sealing resin 50 in a phantom line. In FIG. 17 and later figures, elements identical or similar to those in the semiconductor device A10 of the above embodiment are denoted by the same reference numerals, and descriptions are omitted where appropriate.

In the example shown in FIG. 17, the primary difference lies in the shape of the second wire 45A. Although not shown in the figures, the first wire 42A and the second wire 45A in this variation have the same shapes as those shown in FIG. 15 as viewed in the thickness direction z. That is, the second wire 45A is curved by wire sweep into a convex shape toward the first wire 42A as viewed in the thickness direction z.

In this variation, the second wire 45A includes a first bent portion 453, a second bent portion 454, a first segment 455, and a second segment 456. The first bent portion 453 is positioned close to the third end portion 451, and the second bent portion 454 is positioned close to the fourth end portion 452. The first segment 455 is the portion between the first bent portion 453 and the second bent portion 454, and the second segment 456 is the portion between the second bent portion 454 and the fourth end portion 452. As viewed in the thickness direction z, the first segment 455 extends across the first wire 42A. The first bent portion 453 and the second bent portion 454 are formed, for example, by providing bending points in the path of the bonding tool during wire bonding of the second wire 45A. In FIG. 17, a region bounded by a dotted line indicates a portion in which wire sweep may cause the second wire 45A to extend across the first wire 42A as viewed in the thickness direction z.

In the present variation, the second wire 45A is curved into a convex shape toward the first wire 42A as viewed in the thickness direction z. The second wire 45A extends across the first wire 42A as viewed in the thickness direction z. The second wire 45A is spaced apart from the first wire 42A in the thickness direction z. With this variation, even if the second wire 45A undergoes wire sweep during molding of the sealing resin 50, contact between the adjacent first wire 42A and second wire 45A can be avoided. In the variation shown in FIG. 17, the first segment 455 extends across the first wire 42A. That is, in the region where the second wire 45A may extend across the first wire 42A as viewed in the thickness direction z, the second wire 45A is at a sufficient distance from the first wire 42A in the thickness direction z. Thus, undesirable contact between the first wire 42A and the second wire 45A is reliably prevented. Additionally, the semiconductor device A11 provides the same advantages as the semiconductor device A10, to the extent that they share the same configuration.

### Other Variations in Arrangement of First Wire and Second Wire:

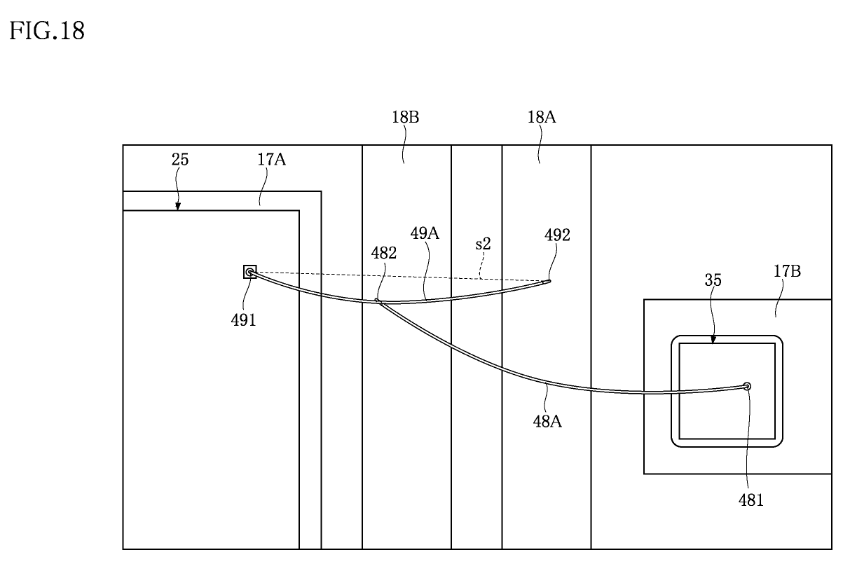

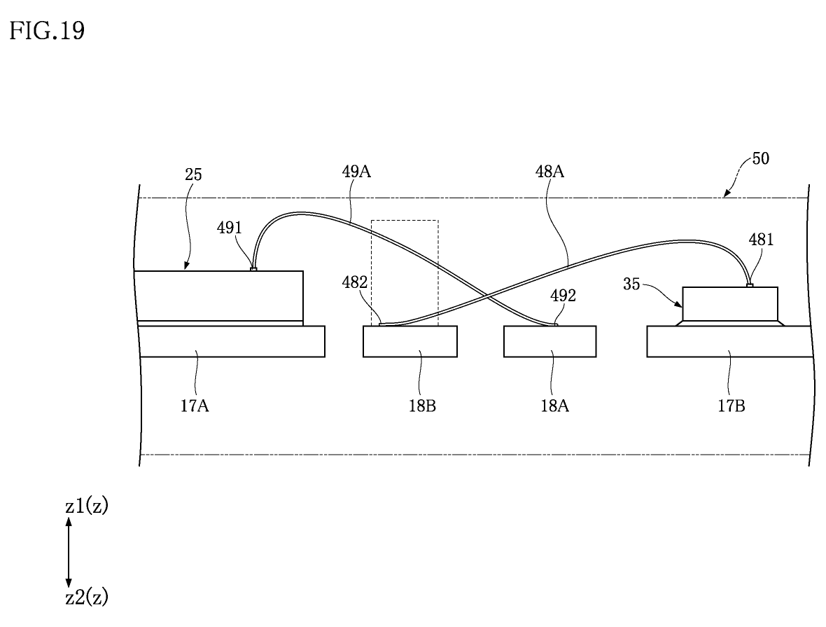

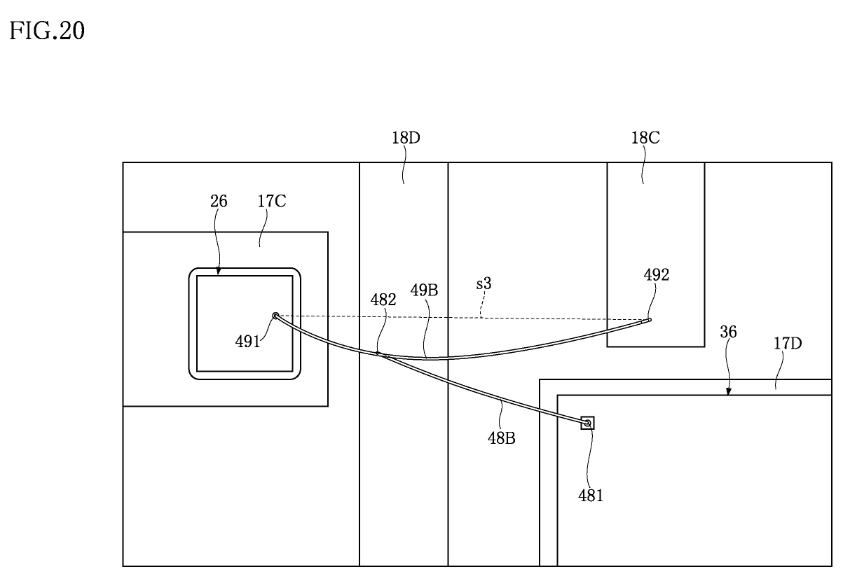

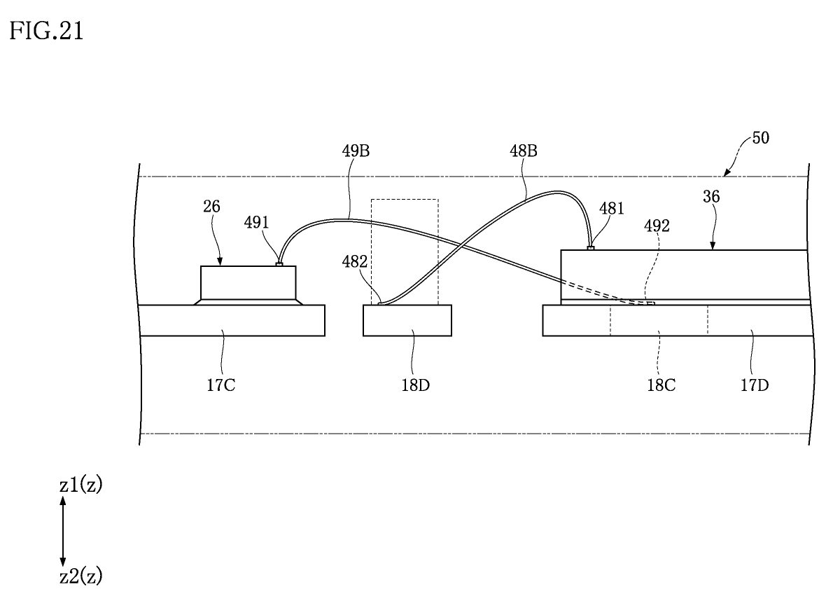

FIGS. 18 to 21 show other variations in the arrangement of a first wire and a second wire. FIG. 18 is a plan view schematically showing the arrangement of the first wire and the second wire according to a variation (first example). FIG. 19 is a lateral view schematically showing the arrangement of the first wire and the second wire shown in FIG. 18. FIG. 20 is a plan view schematically showing the arrangement of a first wire and a second wire according to a variation (second example). FIG. 21 is a lateral view schematically showing the arrangement of the first wire and the second wire shown in FIG. 20. The sealing resin 50 is not shown in FIGS. 18 and 20. For convenience of description, FIGS. 19 and 21 shows the sealing resin 50 as being transparent and represents the outline of the sealing resin 50 in a phantom line.

The variations in wire arrangement shown in FIGS. 18 to 21 are applicable to the semiconductor devices without restriction as to their packaging structures. The semiconductor elements 25, 26, 35, and 36 described below are not limited to any particular type, and may be, for example, switching elements such as MOSFETs, driving or control elements such as ICs or LSIs, or diodes.

The first example in FIGS. 18 and 19 shows the arrangement of the first wire 48A and the second wire 49A. The first wire 48A and the second wire 49A are curved into a convex shape toward the lower side in FIG. 18, by wire sweep during molding of the sealing resin 50.

The first wire 48A has a first end portion 481 and a second end portion 482. The first end portion 481 is bonded to the surface of the semiconductor element 35 on the z1 side in the thickness direction z. The semiconductor element 35 is disposed on the surface of a lead 17B on the z1 side in the thickness direction z. The second end portion 482 is bonded to the surface of a lead 18B on the z1 side in the thickness direction z. The semiconductor element 35 corresponds to an example of the “first element” recited in the present disclosure.

The second wire 49A has a third end portion 491 and a fourth end portion 492. The third end portion 491 is bonded to the surface of the semiconductor element 25 on the z1 side in the thickness direction z. The semiconductor element 25 is disposed on the surface of a lead 17A on the z1 side in the thickness direction z. The fourth end portion 492 is bonded to the surface of a lead 18A on the z1 side in the thickness direction z. The semiconductor element 25 corresponds to an example of the “second element” recited in the present disclosure. In the example shown in FIGS. 18 and 19, the total length of the second wire 49A is shorter than that of the first wire 48A. The third end portion 491, which is bonded to the surface of the semiconductor element 25 on the z1 side in the thickness direction z, is positioned on the z1 side in the thickness direction z with respect to the first end portion 481, which is bonded to the surface of the semiconductor element 35 on the z1 side in the thickness direction z.

As shown in FIG. 18, the second wire 49A is curved by wire sweep into a convex shape toward the first wire 48A as viewed in the thickness direction z. The second wire 49A extends across the first wire 48A as viewed in the thickness direction z. In the example shown in the figure, the second wire 49A extends across the second end portion 482 of the first wire 48A. In contrast, a line segment s2 connecting the third end portion 491 and the fourth end portion 492 does not intersect the first wire 48A as viewed in the thickness direction z. That is, prior to molding of the sealing resin 50, the second wire 49A does not intersect the first wire 48A as viewed in the thickness direction z.

In FIG. 19, a region bounded by a dotted line indicates a portion in which wire sweep may cause the second wire 49A to extend across the first wire 48A as viewed in the thickness direction z. As can be seen from FIGS. 18 and 19, in the portion in which the second wire 49A may extend across the first wire 48A as viewed in the thickness direction z, the second wire 49A is sufficiently spaced apart from the first wire 48A in the thickness direction z.

In the example shown in FIGS. 18 and 19, the second wire 49A is curved into a convex shape toward the first wire 48A as viewed in the thickness direction z. The second wire 49A extends across the first wire 48A as viewed in the thickness direction z. The second wire 49A is spaced apart from the first wire 48A in the thickness direction z. With the variation shown in FIGS. 18 and 19, even if the second wire 49A undergoes wire sweep during molding of the sealing resin 50, contact between the adjacent first wire 48A and second wire 49A can be avoided. Additionally, this variation provides the same advantages as the semiconductor device A10, to the extent that they share the same configuration.

The second example in FIGS. 20 and 21 shows the arrangement of the first wire 48B and the second wire 49B. The first wire 48B and the second wire 49B are curved into a convex shape toward the lower side in FIG. 20, by wire sweep during molding of the sealing resin 50.

The first wire 48B has a first end portion 481 and a second end portion 482. The first end portion 481 is bonded to the surface of the semiconductor element 36 on the z1 side in the thickness direction z. The semiconductor element 36 is disposed on the surface of a lead 17D on the z1 side in the thickness direction z. The second end portion 482 is bonded to the surface of a lead 18D on the z1 side in the thickness direction z. The semiconductor element 36 corresponds to an example of the “first element” recited in the present disclosure.

The second wire 49B has a third end portion 491 and a fourth end portion 492. The third end portion 491 is bonded to the surface of the semiconductor element 26 on the z1 side in the thickness direction z. The semiconductor element 26 is disposed on the surface of a lead 17C on the z1 side in the thickness direction z. The fourth end portion 492 is bonded to the surface of a lead 18C on the z1 side in the thickness direction z. The semiconductor element 26 corresponds to an example of the “second element” recited in the present disclosure. In the example shown in FIGS. 20 and 21, the total length of the second wire 49B is longer than that of the first wire 48B. The third end portion 491, which is bonded to the surface of the semiconductor element 26 on the z1 side in the thickness direction z, is positioned on the z2 side in the thickness direction z with respect to the first end portion 481, which is bonded to the surface of the semiconductor element 36 on the z1 side in the thickness direction z.

As shown in FIG. 20, the second wire 49B is curved by wire sweep into a convex shape toward the first wire 48B as viewed in the thickness direction z. The second wire 49B extends across the first wire 48B as viewed in the thickness direction z. In the example shown in the figure, the second wire 49B extends across the second end portion 482 of the first wire 48B. In contrast, a line segment s3 connecting the third end portion 491 and the fourth end portion 492 does not intersect the first wire 48B as viewed in the thickness direction z. That is, prior to molding of the sealing resin 50, the second wire 49B does not intersect the first wire 48B as viewed in the thickness direction z.

In FIG. 21, a region bounded by a dotted line indicates a portion in which wire sweep may cause the second wire 49B to extend across the first wire 48B as viewed in the thickness direction z. As can be seen from FIGS. 20 and 21, in the portion in which the second wire 49B may extend across the first wire 48B as viewed in the thickness direction z, the second wire 49B is sufficiently spaced apart from the first wire 48B in the thickness direction z.

In the example shown in FIGS. 20 and 21, the second wire 49B is curved into a convex shape toward the first wire 48B as viewed in the thickness direction z. The second wire 49B extends across the first wire 48B as viewed in the thickness direction z. The second wire 49B is spaced apart from the first wire 48B in the thickness direction z. With the variation shown in FIGS. 20 and 21, even if the second wire 49B undergoes wire sweep during molding of the sealing resin 50, contact between the adjacent first wire 48B and second wire 49B can be avoided. Additionally, this variation provides the same advantages as the semiconductor device A10, to the extent that they share the same configuration.

The semiconductor device according to the present disclosure is not limited to the embodiments described above. Various modifications in design may be made freely in the specific structure of each part of the semiconductor device according to the present disclosure.

The present disclosure includes the configurations related to the following clauses.

### Clause 1.

A semiconductor device comprising: one or more leads; one or more semiconductor elements disposed on a first side in a thickness direction with respect to the one or more leads; a plurality of wires each of which is electrically connected to at least one of the one or more leads and the one or more semiconductor elements; and a sealing resin that covers the one or more semiconductor elements, the plurality of wires, and at least a portion of the one or more leads, wherein the plurality of wires include a first wire and a second wire, the second wire is curved in a convex shape toward the first wire as viewed in the thickness direction, and the second wire extends across the first wire as viewed in the thickness direction and is spaced apart from the first wire in the thickness direction.

### Clause 2.

The semiconductor device according to Clause 1, wherein the first wire includes a first end portion at one end and a second end portion at another end, the second wire includes a third end portion at one end and a fourth end portion at another end, and a line segment connecting the third end portion and the fourth end portion does not intersect the first wire as viewed in the thickness direction.

### Clause 3.

The semiconductor device according to Clause 2, wherein the first end portion is positioned on the first side in the thickness direction relative to the second end portion.

### Clause 4.

The semiconductor device according to Clause 3, wherein the third end portion is positioned on the first side in the thickness direction relative to the fourth end portion.

### Clause 5.

The semiconductor device according to Clause 4, wherein the third end portion is positioned closer to the second end portion of the first wire than to the first end portion.

### Clause 6.

The semiconductor device according to Clause 5, wherein the fourth end portion is positioned closer to the first end portion of the first wire than to the second end portion.

### Clause 7.

The semiconductor device according to any one of Clauses 1 to 6, wherein a total length of the second wire is longer than a total length of the first wire.

### Clause 8.

The semiconductor device according to any one of Clauses 3 to 6, wherein the second wire extends across the second end portion of the first wire as viewed in the thickness direction.

### Clause 9.

The semiconductor device according to any one of Clauses 4 to 6, wherein the second wire includes a first bent portion close to the third end portion, a second bent portion close to the fourth end portion, a first segment between the first bent portion and the second bent portion, and a second segment between the second bent portion and the fourth end portion, and the first segment extends across the first wire as viewed in the thickness direction.

### Clause 10.

The semiconductor device according to any one of Clauses 4 to 6, wherein the third end portion is positioned on the first side in the thickness direction relative to the first end portion.

### Clause 11.

The semiconductor device according to any one of Clauses 2 to 6, wherein each of the first wire and the second wire is electrically connected to the one or more semiconductor elements.

### Clause 12.

The semiconductor device according to Clause 11, wherein the one or more semiconductor elements include a first element and a second element, the first end portion is bonded to a portion of the first element on the first side in the thickness direction, the second end portion is bonded to a portion of one of the one or more leads on the first side in the thickness direction, the third end portion is bonded to a portion of the second element on the first side in the thickness direction, and the fourth end portion is bonded to a portion of one of the one or more leads on the first side in the thickness direction.

### Clause 13.

The semiconductor device according to Clause 12, wherein the first element comprises a drive element, and the second element comprises a switching element.

1. A semiconductor device comprising:
one or more leads;
one or more semiconductor elements disposed on a first side in a thickness direction with respect to the one or more leads;
a plurality of wires each of which is electrically connected to at least one of the one or more leads and the one or more semiconductor elements; and
a sealing resin that covers the one or more semiconductor elements, the plurality of wires, and at least a portion of the one or more leads,
wherein the plurality of wires include a first wire and a second wire,
the second wire is curved in a convex shape toward the first wire as viewed in the thickness direction, and
the second wire extends across the first wire as viewed in the thickness direction and is spaced apart from the first wire in the thickness direction.

2. The semiconductor device according to claim 1, wherein the first wire includes a first end portion at one end and a second end portion at another end,
the second wire includes a third end portion at one end and a fourth end portion at another end, and
a line segment connecting the third end portion and the fourth end portion does not intersect the first wire as viewed in the thickness direction.

3. The semiconductor device according to claim 2, wherein the first end portion is positioned on the first side in the thickness direction relative to the second end portion.

4. The semiconductor device according to claim 3, wherein the third end portion is positioned on the first side in the thickness direction relative to the fourth end portion.

5. The semiconductor device according to claim 4, wherein the third end portion is positioned closer to the second end portion of the first wire than to the first end portion.

6. The semiconductor device according to claim 5, wherein the fourth end portion is positioned closer to the first end portion of the first wire than to the second end portion.

7. The semiconductor device according to claim 1, wherein a total length of the second wire is longer than a total length of the first wire.

8. The semiconductor device according to claim 3, wherein the second wire extends across the second end portion of the first wire as viewed in the thickness direction.

9. The semiconductor device according to claim 4, wherein the second wire includes a first bent portion close to the third end portion, a second bent portion close to the fourth end portion, a first segment between the first bent portion and the second bent portion, and a second segment between the second bent portion and the fourth end portion, and
the first segment extends across the first wire as viewed in the thickness direction.

10. The semiconductor device according to claim 4, wherein the third end portion is positioned on the first side in the thickness direction relative to the first end portion.

11. The semiconductor device according to claim 2, wherein each of the first wire and the second wire is electrically connected to the one or more semiconductor elements.

12. The semiconductor device according to claim 11, wherein the one or more semiconductor elements include a first element and a second element,
the first end portion is bonded to a portion of the first element on the first side in the thickness direction,
the second end portion is bonded to a portion of one of the one or more leads on the first side in the thickness direction,
the third end portion is bonded to a portion of the second element on the first side in the thickness direction, and
the fourth end portion is bonded to a portion of one of the one or more leads on the first side in the thickness direction.

13. The semiconductor device according to claim 12, wherein the first element comprises a drive element, and
the second element comprises a switching element.
